(19) United States
(12) Patent Application Publication
(10) Pub. No.: US 2026/0052885 A1
(43) Pub. Date: Feb. 19, 2026

(54) DISPLAY PANEL, AND DISPLAY APPARATUS

(71) Applicants: KunShan Go-Visionox Opto-Electronics Co., Ltd., Kunshan (CN); Hefei Visionox Technology Co., Ltd., Hefei (CN)

(72) Inventors: Zhen FU, Hefei (CN); Xu QIAN, Hefei (CN); Ying SHEN, Kunshan (CN); Shuangbing ZHANG, Hefei (CN)

(73) Assignees: KunShan Go-Visionox Opto-Electronics Co., Ltd., Kunshan (CN); Hefei Visionox Technology Co., Ltd., Hefei (CN)

(21) Appl. No.: 19/313,756

(22) Filed: Aug. 28, 2025

(30) Foreign Application Priority Data
Jun. 28, 2024 (CN) 202410866003.7

(51) Int. Cl. H10K 59/80; H10K 59/122

(52) U.S. Cl. CPC H10K 59/873; H10K 59/122

(57) ABSTRACT

The embodiments of the present application provide a display panel and an electronic device, which relate to the field of display technology. In the display panel, the isolation structure is located on the substrate and encloses an isolation opening. The light-emitting device is at least partially located within the isolation opening. The encapsulation unit is located on a side of the light-emitting device away from the substrate, extends along a sidewall of the isolation structure facing the isolation opening, and reaches a side of the isolation structure away from the substrate. The encapsulation unit includes a first encapsulation portion in contact with the isolation structure, and a film thickness of the first encapsulation portion is uniform. In the above structure, the film thickness of the first encapsulation portion is uniform, and the overall resistance of the first encapsulation portion to deformation stress is strong, making it less prone to rupture due to external forces. This improves the encapsulation effect of the encapsulation unit on the light-emitting device and ensures the display performance of the display panel.

### CROSS-REFERENCE TO RELATED APPLICATIONS

The present application claims priority to the Chinese Patent Application 202410866003.7, filed on Jun. 28, 2024, and the entire contents of the aforementioned application are hereby incorporated by reference in its entirety.

### TECHNICAL FIELD

The present application relates to the technical field of display, and particularly to a display panel and an electronic device.

### BACKGROUND

The organic light emitting diode (OLED) is regarded as the next-generation flat panel display technology after the liquid crystal display technology, which is widely applied in various consumer electronic products such as mobile phones, televisions, laptop computers and desktop computers due to its excellent color and image quality, and has become the mainstream in display panels.

However, the process performance of current OLED display products still needs to be further improved.

### SUMMARY

In order to overcome the technical problem mentioned in the above Background, the present application provides a display panel and an electronic device.

In a first aspect of the present application, a display panel is provided, including:
a substrate;
an isolation structure, located on one side of the substrate, the isolation structure encircling a plurality of isolation openings;
a light-emitting device, the light-emitting devices being at least partially located within a corresponding one of the isolation openings; and
an encapsulation unit, located on a side of the light-emitting device away from the substrate, and for each of the isolation openings, the encapsulation unit extending through the isolation structure toward a side wall of the isolation opening to a side of the isolation structure away from the substrate;
wherein the encapsulation unit includes a first encapsulation portion in contact with the isolation structure, and a film thickness of the first encapsulation portion is uniform.
   the encapsulation unit further includes a second encapsulation portion covering a side of the light-emitting device away from the substrate, and a film thickness of the second encapsulation portion is uniform;
preferably, an average film thickness of the second encapsulation portion is greater than or equal to an average film thickness of the first encapsulation portion; and
preferably, the average film thickness of the first encapsulation portion is the same as the average film thickness of the second encapsulation portion.
   a difference in film thickness of the first encapsulation portion at different positions is less than one fifth of an average film thickness of the first encapsulation portion, and a difference in film thickness of the second encapsulation portion at different positions is less than one fifth of an average film thickness of the second encapsulation portion; and
a difference between an average film thickness of the first encapsulation portion and an average film thickness of the second encapsulation portion is less than one tenth of the average film thickness of the first encapsulation portion or one tenth of the average film thickness of the second encapsulation portion.
   the isolation structure includes a conductive portion and an isolation portion; and
the isolation portion includes a first isolation portion located on a side of the conductive portion away from the substrate, and on a first cross-section perpendicular to a plane where the substrate is located and in a direction of a line connecting centers of two adjacent isolation openings, a dimension of the first isolation portion gradually decreases from the side of the isolation portion away from the substrate toward a direction close to the substrate.

Within each of the isolation openings, a first included angle between a side wall of the first isolation portion and a bottom surface on a side of the first isolation portion facing the substrate is an obtuse angle;
on the first cross-section, a cross-sectional shape of the first isolation portion is an inverted trapezoid; and
within each of the isolation openings, a second included angle between a surface on a side of the first encapsulation portion facing the isolation opening and a surface on a side of the second encapsulation portion away from the substrate is an acute angle.

In a possible implementation of the present application, a thickness of the isolation portion is 1 to 10 times a thickness of the conductive portion; and
an orthographic projection of the isolation portion on the substrate is located within an orthographic projection of the conductive portion on the substrate.

In a possible implementation of the present application, on the first cross-section, a cross-sectional shape of the conductive portion is a trapezoid;
an orthographic projection, on the substrate, of a bottom surface of the first isolation portion facing the substrate is located within an orthographic projection, on the substrate, of a top surface of the conductive portion away from the substrate; and
within each of the isolation openings, a third included angle between a side wall of the first isolation portion facing the isolation opening and a side wall of the conductive portion facing the isolation opening is an obtuse angle.

In a possible implementation of the present application, the isolation portion further includes a second isolation portion located on a side of the first isolation portion close to the conductive portion, and on the first cross-section, a dimension of the second isolation portion gradually increases from a side of the second isolation portion away from the substrate toward the direction close to the substrate;
the first isolation portion and the second isolation portion are made of the same material;
within each of the isolation openings, an orthographic projection of the second isolation portion on the substrate is located within an orthographic projection of the first isolation portion on the substrate;
an orthographic projection of the conductive portion on the substrate extends toward the isolation opening relative to the orthographic projection of the first isolation portion on the substrate; and
within each of the isolation openings, a fourth included angle between a side wall of the second isolation portion facing the isolation opening and a side wall of the conductive portion facing the isolation opening is an obtuse angle, and a fifth included angle between a side wall of the first isolation portion facing the isolation opening and the side wall of the second isolation portion facing the isolation opening is an obtuse angle.

In a possible implementation of the present application, the isolation portion further includes a third isolation portion located on a side of the first isolation portion away from the substrate, the third isolation portion extending relative to the first isolation portion toward the isolation opening; and
within each of the isolation openings, a sixth included angle between a side of the third isolation portion facing the substrate and a side of the first isolation portion facing the isolation opening is an obtuse angle.

In a possible implementation of the present application, the isolation structure further includes a blocking portion located on a side of the isolation portion away from the substrate;
an orthographic projection of the blocking portion on the substrate coincides with the orthographic projection of the isolation portion on the substrate;
a material of the blocking portion includes a corrosion-resistant material; and
the material of the blocking portion includes titanium.

In a possible implementation of the present application, a gap is provided between adjacent isolation structures, and the display panel further includes a first touch trace disposed in the same layer as the conductive portion, the first touch trace being located in the gap between the adjacent isolation structures;
alternatively, the display panel further includes a touch functional layer located on a side of the isolation structure away from the substrate, the touch functional layer including a plurality of second touch traces, and an orthographic projection of each of the second touch traces on the substrate at least partially overlapping with an orthographic projection of the isolation structure on the substrate.

In a possible implementation of the present application, the display panel includes a first active area and a second active area at least partially surrounding the first active area;
the isolation structure further includes a light-transmitting opening, where the isolation opening and the light-transmitting opening are located in the first active area, and the light-transmitting opening is located between adjacent isolation openings; and
the conductive portion is opaque, and the orthographic projection of the conductive portion on the substrate is outside an orthographic projection of the light-transmitting opening on the substrate.

In a possible implementation of the present application, the display panel further includes a pixel defining layer located on one side of the substrate, the isolation structure being located on a side of the pixel defining layer away from the substrate;
the pixel defining layer defines a plurality of pixel openings on the substrate, and an orthographic projection of each of the pixel openings on the substrate is located within an orthographic projection of each of the isolation opening on the substrate;
in a direction away from the substrate, the light-emitting device includes a first electrode, a light-emitting material layer and a second electrode that are stacked, the second electrode overlapping with the conductive portion; and
an orthographic projection of the first electrode on the substrate partially overlaps with an orthographic projection of the isolation structure on the substrate.

In a possible implementation of the present application, the light-emitting material layer includes at least two emission layers that are stacked;
the at least two emission layers have the same color, and the light-emitting material layer further includes a charge generation layer located between adjacent emission layers;
the light-emitting material layer includes a hole injection layer, a first hole transport layer, a first electron-blocking layer, a first emission layer, a first hole block layer, a first electron-transport layer, an N-type charge generation layer, a P-type charge generation layer, a second hole transport layer, a second electron-blocking layer, a second emission layer, a second hole block layer, a second electron transport layer, and an electron injection layer that are sequentially stacked in the direction away from the substrate; and
preferably, orthographic projections of the hole injection layer, the first hole transport layer, the N-type charge generation layer, and the second hole transport layer on the substrate are located outside the orthographic projection of the conductive portion on the substrate.

In a possible implementation of the present application, two adjacent encapsulation units for encapsulating two light-emitting devices of different colors are separated on the side of the isolation structure away from the substrate;
and/or adjacent encapsulation units for encapsulating light-emitting devices of the same color are continuous on a side of the isolation structure away from the substrate.

In a possible implementation of the present application, two adjacent encapsulation units for encapsulating two light-emitting devices are separated on the side of the isolation structure away from the substrate; and
a gap is provided between the isolation structure and the encapsulation unit on the side of the isolation structure away from the substrate

In a possible implementation of the present application, the display panel further includes a plurality of filter units and light-absorbing units, each of the filter units is filled in the isolation opening, each of the light-absorbing units is disposed on a side of the isolation structure away from the substrate, and an orthographic projection of the light-absorbing unit on the substrate overlaps with the orthographic projection of the isolation structure on the substrate.

Preferably, a material of the first isolation portion includes a light-absorbing material, and the first isolation portion is reused as a light-absorbing unit;
an orthographic projection of the filter unit on the substrate partially overlaps with the orthographic projection of the isolation portion on the substrate; and
a light output color of the filter unit is the same as a light-emitting color of the light-emitting device in the isolation opening.

In a possible implementation of the present application, the display panel further includes a first encapsulation layer;
the first encapsulation layer is located on a side of the encapsulation unit away from the substrate, and the first encapsulation layer has a flat surface on a side thereof away from the substrate;
the display panel further includes a second encapsulation layer located on the side of the first encapsulation layer away from the substrate; and
the encapsulation units and the second encapsulation layer are inorganic encapsulation layers, and the first encapsulation layer is an organic encapsulation layer.

In a second aspect of the present application, a display panel is further provided, including:
a substrate;
an isolation structures located on one side of the substrate, and the isolation structure encircling a plurality of isolation openings;
a light-emitting device, each of the light-emitting devices being at least partially located within a corresponding one of the isolation openings; and
an encapsulation unit, located on a side of the light-emitting device away from the substrate, and for each of the isolation openings, the encapsulation unit extending through a corresponding one of the isolation structures toward a side wall of the isolation opening to a side of the isolation structure away from the substrate;
where the isolation structure includes a first isolation portion and a second isolation portion that are stacked in a direction away from the substrate, the second isolation portion extending toward the isolation opening relative to the first isolation portion, and on a first cross-section perpendicular to a plane where the substrate is located and in a direction of a line connecting centers of two adjacent isolation openings, a cross-sectional shape of the first isolation portion being an inverted trapezoid; and
a thickness of the encapsulation unit in contact with the first isolation portion is the same as a thickness of the encapsulation unit in contact with the second isolation portion.

In a third aspect of the present application, a display panel is further provided, including:
a substrate;
an isolation structure, located on one side of the substrate, and the isolation structure encircling a plurality of isolation openings;
a light-emitting device, each of the light-emitting devices being at least partially located within a corresponding one of the isolation openings; and
an encapsulation unit, located on a side of the light-emitting device away from the substrate, and the isolation structure encircling a plurality of isolation openings extending through a corresponding one of the isolation structures toward a side wall of the isolation opening to a side of the isolation structure away from the substrate;
where the isolation structure includes a first isolation portion and a second isolation portion that are stacked in a direction away from the substrate, the second isolation portion extending toward the isolation opening relative to the first isolation portion, and on a first cross-section perpendicular to a plane where the substrate is located and in a direction of a line connecting centers of two adjacent isolation openings, a cross-sectional shape of the first isolation portion being a trapezoid; and
a thickness of the encapsulation unit in contact with the first isolation portion is the same as a thickness of the encapsulation unit in contact with the second isolation portion.

In a fourth aspect of the present application, an electronic device is further provided, including a display panel according to any one of possible implementations in the first aspect, the second aspect, or the third aspect.

An embodiment of the present application provides a display panel and an electronic device. In the display panel, isolation structures are located on a substrate and define isolation openings. Each of light-emitting devices is at least partially located in a corresponding one of the isolation openings. Each of encapsulation units is located on a side of the light-emitting device away from the substrate and extends through a corresponding one of the isolation structures toward a side wall of the isolation opening to a side of the isolation structure away from the substrate. The encapsulation unit includes a first encapsulation portion in contact with the isolation structure, and a film thickness of the first encapsulation portion is uniform. In the above structure, the film thickness of the first encapsulation portion is uniform, the overall resistance to deformation stress of the first encapsulation portion is strong, and it is not easy to rupture due to an external force. It can improve the encapsulation effect of the encapsulation unit on the light-emitting device and ensure the display effect of the display panel.

### BRIEF DESCRIPTION OF THE DRAWINGS

In order to illustrate the technical solutions of embodiments of the present application more clearly, the drawings required in the embodiments will be briefly introduced below. It should be understood that the following drawings only show some embodiments of the present application, and therefore should not be construed as a limitation on the scope. For those of ordinary skill in the art, other related drawings can be obtained from these drawings without involving any inventive effort.

FIG. 1 illustrates a first schematic diagram of part of a film layer structure in a display panel according to an embodiment of the present application;

FIG. 2 illustrates a positional relationship diagram of isolation structures and isolation openings in the display panel according to an embodiment of the present application;

FIG. 3 illustrates a first cross-sectional schematic diagram of the display panel along line AA in FIG. 2;

FIG. 4 illustrates a second cross-sectional schematic diagram of the display panel along line AA in FIG. 2;

FIG. 5 illustrates a third cross-sectional schematic diagram of the display panel along line AA in FIG. 2;

FIG. 6 illustrates a fourth cross-sectional schematic diagram of the display panel along line AA in FIG. 2;

FIG. 7 illustrates a fifth cross-sectional schematic diagram of the display panel along line AA in FIG. 2;

FIG. 8 illustrates a sixth cross-sectional schematic diagram of the display panel along line AA in FIG. 2;

FIG. 9 illustrates a schematic diagram showing the distribution of regions of the display panel;

FIG. 10 is a cross-sectional schematic diagram of a first active area in FIG. 9;

FIG. 11 illustrates a seventh cross-sectional schematic diagram of the display panel along line AA in FIG. 2;

FIG. 12 illustrates a schematic diagram of a possible film layer structure of a light-emitting device;

FIG. 13 illustrates a schematic diagram showing the relationship between a film thickness and stress;

FIG. 14 illustrates an eighth cross-sectional schematic diagram of the display panel along line AA in FIG. 2;

FIG. 15 illustrates a ninth cross-sectional schematic diagram of the display panel along line AA in FIG. 2;

FIG. 16 illustrates a second schematic diagram of part of a film layer structure in a display panel according to an embodiment of the present application; and

FIG. 17 illustrates a third schematic diagram of part of a film layer structure in a display panel according to an embodiment of the present application.

List of reference signs: 1—Display panel; 11—Substrate; 12—Isolation structure; 1201—Isolation opening; 1202—Light-transmitting opening; 121—Conductive portion; 122—Isolation portion; 1221—First isolation portion; 1222—Second isolation portion; 1223—Third isolation portion; 12231—Groove; 13—Pixel defining layer; 1301—Pixel opening; 14—Light-emitting device; 141—First electrode; 142—Light-emitting material layer; 143—Second electrode; 151—Encapsulation unit; 1511—First encapsulation portion; 1512—Second encapsulation portion; 152—First encapsulation layer; 153—Second encapsulation layer; 16—Touch functional layer; 161—First touch trace; 162—Second touch trace; 17—Filter unit; 18—Light-absorbing unit.

### DETAILED DESCRIPTION OF THE EMBODIMENTS

In order to make the objectives, technical solutions and advantages of embodiments of the present application clearer, the technical solutions in the embodiments of the present application will be described clearly and completely below with reference to the accompanying drawings in the embodiments of the present application. Apparently, the embodiments described are some of, rather than all of, the embodiments of the present application. In general, assemblies of the embodiments of the present application described and shown in the accompanying drawings herein can be arranged and designed in various configurations.

Thus, the following detailed description of the embodiments of the present application provided in the accompanying drawings is not intended to limit the scope of the present application as claimed, but is merely representative of the selected embodiments of the present application. Based on the embodiments of the present application, all other embodiments obtained by those of ordinary skill in the art without involving any inventive effort shall fall within the scope of protection of the present application.

It should be noted that like items are denoted by like numerals and letters in the following drawings. Therefore, once a specific item is defined in one of the drawings, the item needs not to be further defined and explained in subsequent drawings.

In the description of the present application, it should be noted that orientations or position relationships indicated by terms such as “center,” “upper,” “lower”, “vertical”, “horizontal”, “inner”, and “outer” are based on orientations or position relationships shown in the drawings or the orientations or position relationships in which a product of the present application is customarily placed in use, and are merely intended to facilitate and simplify the description of the present application, rather than indicating or implying that the device or element considered must have a particular orientation or be constructed and operated in a particular orientation, and therefore not to be construed as limiting the present application. In addition, the terms such as “first”, “second” and “third” are merely intended to distinguish the description, and are not to be construed as indicating or implying relative importance.

It should be noted that different features in the embodiments of the present application may be combined with each other without conflicts.

Increasing the density (i.e. pixel density) of light-emitting devices in a display panel is an important way to improve the display effect. However, display panels currently made by using the fine metal mask (FMM) technology are unable to further increase the density of light-emitting devices due to technical limitations. The inventors have found, after long-term research, that in order to solve the technical problem that the density of light-emitting devices cannot be further increased, isolation structures are provided in some display panels, and during the full-layer evaporation of light-emitting material layers and cathodes, the light-emitting material layers and the cathodes can be disconnected at the position of the isolation structures, and light-emitting devices of different colors can be formed in different isolation openings by means of multiple evaporation and multiple etching processes, i.e., patterning of the light-emitting devices.

Reference is made to relevant technical solutions of an isolation structure and an encapsulation layer disclosed in patents PCT/CN2023/134518, 202310759370.2, 202310740412.8, 202310707209.0, 202311499823.9, 202310692671.8, 202311091555.7, and 202311346196.5, the contents of which are incorporated herein by reference.

In the above-mentioned display panel, the inventors have found that after the display panel is deformed due to the action of an external force, the display effect of the display panel will be affected. Through research, the inventors have found that the main reasoning for the above technical problems is the rupture of an inorganic encapsulation layer for encapsulating the light-emitting devices, which makes the inorganic encapsulation layer fail to encapsulate the light-emitting devices, allowing moisture to invade the light-emitting devices, thereby affecting the display effect of the display panel. After conducting a technical analysis of a rupture position of the inorganic encapsulation layer, the inventors have found that the rupture position of the inorganic encapsulation layer is mainly located in an area where a film thickness of the inorganic encapsulation layer is relatively small in the isolation structure, and this area is mainly concentrated in an area where the inorganic encapsulation layer is in direct contact with the isolation structure.

In order to solve the above-described problems, the inventors have innovatively designed the following technical solutions. The specific implementations of the present application will be described in detail below with reference to the accompanying drawings. It should be noted that the defects of the above solutions in the prior art are the results obtained by the inventors after practice and careful research. Therefore, the process of discovering the above technical problem and the solutions proposed in the following embodiments for the above problem should be regarded as the contributions made by the inventors to the present application during invention and creation, and should not be construed as the technical content that is well known to those skilled in the art.

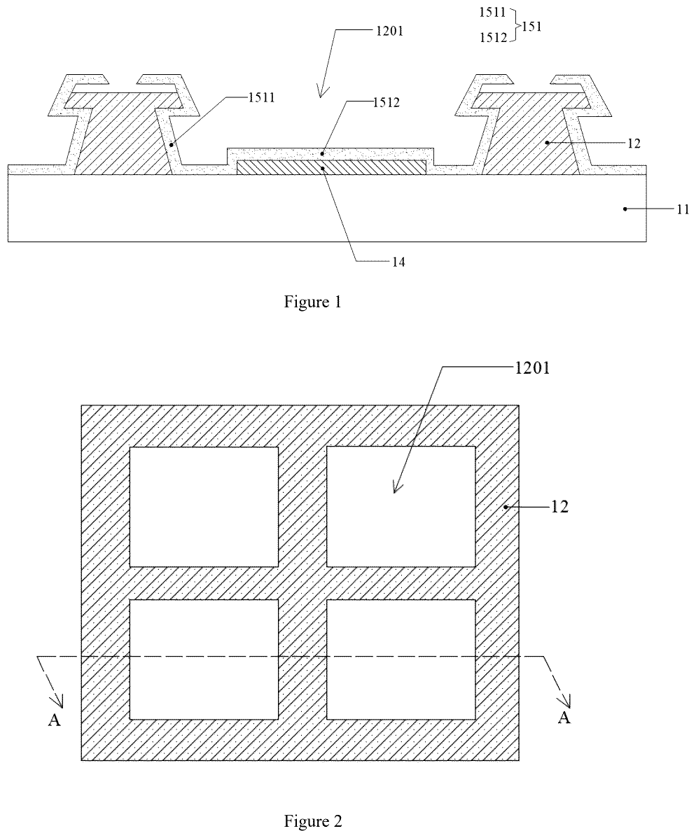

Referring to FIGS. 1 and 2, FIG. 1 illustrates a structural schematic diagram of a display panel according to an embodiment of the present application, and FIG. 2 illustrates a schematic diagram showing the distribution of isolation structures and isolation openings in FIG. 1. In this embodiment, the display panel 1 includes a substrate 11, isolation structures 12, light-emitting devices 14 and encapsulation units 151. The isolation structures 12 are located on the substrate 11 and define isolation openings 1201. The substrate 11 is of a multi-layer structure, and the substrate 11 includes at least a plurality of metal layers and an insulating layer located between adjacent metal layers. A pixel drive circuit for providing driving signals to the light-emitting devices is formed in the substrate 11.

Each of the light-emitting devices 14 is at least partially located in each of the isolation openings 1201. At least one light-emitting device 14 may be disposed in one isolation opening 1201. Preferably, one light-emitting device 14 is disposed in one isolation opening 1201, where the light-emitting devices 14 include light-emitting devices of various colors, for example, the light-emitting devices 14 include a red light-emitting device, a green light-emitting device and a blue light-emitting device.

Each of the encapsulation units 151 is located on a side of a corresponding one of the light-emitting devices 14 away from the substrate 11 and extends through a corresponding one of the isolation structures 12 toward a side wall of the isolation opening 1201 to a side of the isolation structure 12 away from the substrate 11. The encapsulation unit 151 is configured to encapsulate the light-emitting device 14 in the isolation opening 1201.

In this embodiment, the encapsulation unit 151 includes a first encapsulation portion 1511 in contact with the isolation structure 12. A film thickness of the first encapsulation portion 1511 is uniform. The uniform film thickness refers to a thickness difference of the first encapsulation portion 1511 at different positions on a side wall of the isolation structure 12 facing a corresponding one of the isolation openings, which is very small relative to the film thickness of the first encapsulation portion itself, and is at least less than one twentieth of the thickness. For example, the thickness of the first encapsulation portion 1511 is 2000 angstroms, and the difference in thickness at various positions on the side wall of the isolation structure facing the isolation opening is less than 100 angstroms.

In this embodiment, the first encapsulation portion 1511 with the uniform film thickness can be prepared by a single process or a plurality of processes. When the plurality of processes are used to complete the preparation of the first encapsulation portion 1511, the thickness of the first encapsulation portion 1511 can be adjusted through a plurality of processes so that the final first encapsulation portion 1511 has a uniform film thickness. For example, an original encapsulation portion can be made first, and then an area where a film layer in the encapsulation portion is too thin can be re-filmed to increase the film thickness of the area, or an area where the film layer in the encapsulation portion is too thick can be thinned to reduce the film thickness of the area, so as to obtain the final first encapsulation portion 1511.

In the above structure, the film thickness of the first encapsulation portion 1511 is uniform, the overall resistance to deformation stress of the first encapsulation portion 1511 is strong, and it is not easy to rupture due to an external force. It can improve the encapsulation effect of the encapsulation unit 151 on the light-emitting device 14 and ensure the display effect of the display panel 1.

Further, referring to FIG. 1 again, the encapsulation unit 15 further includes a second encapsulation portion 1512 covering the side of the light-emitting device 14 away from the substrate 11. The film thickness of the second encapsulation portion 1512 is uniform.

The average film thickness of the second encapsulation portion 1512 is greater than or equal to the average film thickness of the first encapsulation portion 1511. Preferably, in order to improve the resistance to deformation stress of the entire encapsulation unit 15, in this embodiment, the average film thickness of the first encapsulation portion 1511 is the same as the average film thickness of the second encapsulation portion 1512.

Specifically, in this embodiment, a difference in film thickness of the first encapsulation portion 1511 at different positions is less than one fifth of the average film thickness of the first encapsulation portion 1511. Among them, the average film thickness of the first encapsulation portion 1511 can be obtained by averaging the film thicknesses measured at various positions (for example, 6 positions). It can be understood that the more positions are measured, the more accurate the average film thickness obtained. The difference in film thickness of the first encapsulation portion 1511 at different positions refers to the difference between the film thicknesses measured at any two measurement positions among various measurement positions. For example, the difference in film thickness of the first encapsulation portion 1511 at different positions may be less than one tenth, one ninth, one eighth, one seventh, one sixth or one fifth, etc., of the average film thickness of the first encapsulation portion 1511.

Similarly, a difference in film thickness of the second encapsulation portion 1512 at different positions is less than one fifth of the average film thickness of the second encapsulation portion 1512. The average film thickness of the second encapsulation portion 1512 can be obtained by averaging the film thicknesses measured at various positions. It can be understood that the more positions are measured, the more accurate the average film thickness obtained. The difference in film thickness of the second encapsulation portion 1512 at different positions refers to the difference between the film thicknesses measured at any two measurement positions among various measurement positions. For example, the difference in film thickness of the second encapsulation portion 1512 at different positions may be less than one tenth, one ninth, one eighth, one seventh, one sixth or one fifth, etc., of the average film thickness of the second encapsulation portion 1512.

In this embodiment, the film thickness of the first encapsulation portion 1511 and the film thickness of the second encapsulation portion 1512 are the same, which means that the difference between the two film layers is very small. In detail, the difference between the average film thickness of the first encapsulation portion 1511 and the average film thickness of the second encapsulation portion 1512 is less than one tenth of the average film thickness of the first encapsulation portion 1511 or one tenth of the average film thickness of the second encapsulation portion 1512, that is, the film thickness of the first encapsulation portion 1511 and the film thickness of the second encapsulation portion 1512 can be considered to be the same. For example, the difference between the average film thickness of the first encapsulation portion 1511 and the average film thickness of the second encapsulation portion 1512 is less than one twentieth, one nineteenth, one eighteenth, one sixteenth, one fourteenth, one thirteenth, one twelfth or one tenth, etc., of the average film thickness of the first encapsulation portion 1511 (second encapsulation portion 1512).

In order to reduce the preparation cost of the display panel 1, the first encapsulation portion 1511 with a uniform film thickness can be formed through a single process. In order to complete the preparation of the first encapsulation portion 1511 through a single process, the present embodiment improves the morphology of the isolation structure 12. The following describes the isolation structure of the first encapsulation portion 1511 with a uniform film thickness that can be formed through a single process.

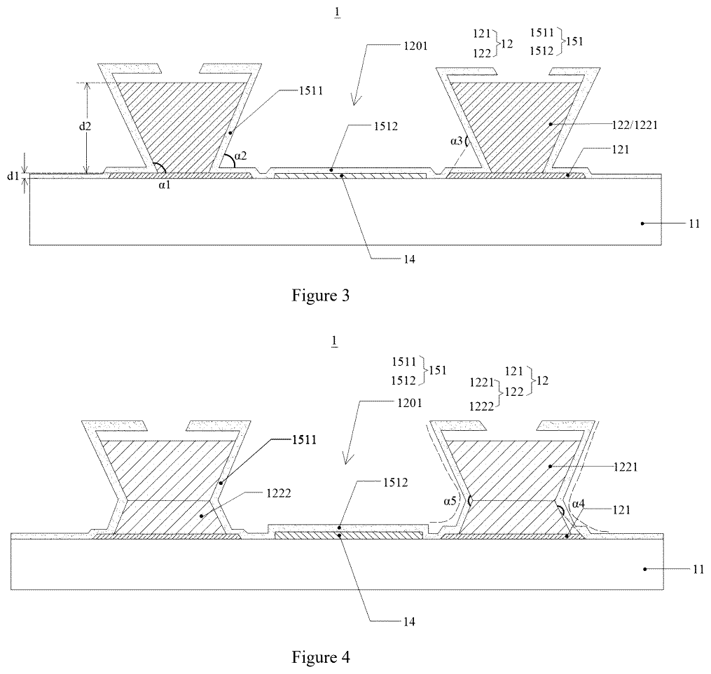

In a possible implementation of this embodiment, referring to FIG. 3, the isolation structure 12 includes a conductive portion 121 and an isolation portion 122, the isolation portion 122 includes a first isolation portion 1221, the first isolation portion 1221 is located on a side of the conductive portion 121 away from the substrate 11, and on a first cross-section perpendicular to a plane where the substrate 11 is located and in a direction of a line connecting centers of two adjacent isolation openings 1201 (direction AA in FIG. 2), a dimension of the first isolation portion 1221 gradually decreases from the side of the isolation portion 121 away from the substrate 11 toward a direction close to the substrate 11.

In the above structure, the above shape of the first isolation portion 1221 can ensure that an evaporated film layer is disconnected at the position of the first isolation portion. In addition, the first isolation portion 1221 forms a cavity that is narrower at the top and wider at the bottom, the cavity has good conductivity, and in the process of preparing the encapsulation unit 151, a film-forming material can flow along a wall of the cavity after entering the cavity, so that the film-forming material will not form a film quickly on a bottom wall of the cavity, which can reduce a narrowing speed of a cavity opening so that the film-forming material can continuously form a film on the isolation portion, forming an encapsulation unit 151 with a uniform film thickness, thereby improving a film stress resistance of the encapsulation unit 151 and its encapsulation effect on the light-emitting device 14.

Referring to FIG. 3 again, a first included angle α1 between a side wall of the first isolation portion 1221 that is configured to provide the isolation opening 1201 and a bottom surface on a side of the first isolation portion 1221 facing the substrate 11 is an obtuse angle. In this way, the isolation opening 121 formed in the first isolation portion 1221 can have the cavity that is narrower at the top and wider at the bottom. For example, on the first cross-section, the cross-sectional shape of the first isolation portion 1221 is an inverted trapezoid. Preferably, the inverted trapezoid may be an isosceles trapezoid. A second included angle α2 between a surface on a side of the first encapsulation portion 1511 away from the isolation structure 12 and a surface on a side of the second encapsulation portion 1512 away from the substrate 11 is an acute angle.

Referring to FIG. 3 again, a thickness d2 of the isolation portion 122 is 1 to 10 times a thickness d1 of the conductive portion 121. For example, the thickness d2 of the isolation portion 122 is 1, 1.05, 1.23, 1.55, 2.15, 3.05, 4.33, 5.25, 6.15, 7.25, 8.23, 8.79, 9.12, 9.55, 9.87, or 10 times the thickness d1 of the conductive portion 121.

In this embodiment, an orthographic projection of the isolation portion 122 on the substrate 11 is located within an orthographic projection of the conductive portion 121 on the substrate 11, which facilitates overlapping of the conductive portion 121 with an evaporated electrode.

Referring to FIG. 3 again, on the first cross-section, the cross-sectional shape of the conductive portion 121 is a trapezoid, that is, a dimension of the conductive portion 121 gradually increases from the side of the conductive portion 121 away from the substrate 11 toward the direction close to the substrate 11. Optionally, the cross-sectional shape of the conductive portion 121 is an isosceles trapezoid.

The surface of the first isolation portion 1221 facing the substrate 11 has a first orthographic projection on the substrate 11, and a top surface of the conductive portion 121 away from the substrate 11 has a second orthographic projection on the substrate 11. The first orthographic projection is located within the second orthographic projection, and an area of the first orthographic projection is smaller than an area of the second orthographic projection.

In a direction toward the isolation opening 1201, a third included angle α3 between a side wall of the first isolation portion 1221 and a side wall of the conductive portion 121 is an obtuse angle. Such an arrangement allows the side wall of the first isolation portion 1221 and the side wall of the conductive portion 121 to form an arc-like guide surface, allowing the film-forming material to move smoothly on the side walls of the first isolation portion 1221 and the conductive portion 121, so as to form an encapsulation unit 151 with a uniform film thickness on surfaces of the side walls of the two.

In another implementation of this embodiment, referring to FIG. 4, the isolation portion 122 further includes a second isolation portion 1222 located on a side of the first isolation portion 1221 close to the conductive portion 121. On the first cross-section, a dimension of the second isolation portion 1222 gradually increases from a side of the second isolation portion 1222 away from the substrate 11 toward the direction close to the substrate 11.

The materials of the first isolation portion 1221 and the second isolation portion 1222 may be the same or different. Preferably, the materials of the first isolation portion 1221 and the second isolation portion 1222 are the same. For example, the materials of the first isolation portion 1221 and the second isolation portion 1222 are organic materials.

Optionally, an orthographic projection of the second isolation portion 1222 on the substrate 11 is located within an orthographic projection of the first isolation portion 1221 on the substrate 11, that is, an area of the orthographic projection of the second isolation portion 1222 on the substrate 11 is smaller than an area of the orthographic projection of the first isolation portion 1221 on the substrate 11.

In this implementation, the thickness of the conductive portion 121 is much smaller than the sum of the thicknesses of the first isolation portion 1221 and the second isolation portion 1222. In order to ensure that the subsequently evaporated cathode can be overlapped on the conductive portion 121, the conductive portion 121 extends relative to the first isolation portion 1221, that is, the orthographic projection of the conductive portion 121 on the substrate 11 extends toward the isolation opening 1201 relative to the orthographic projection of the first isolation portion 1221 on the substrate 11.

In this implementation, in the direction toward the isolation opening 1201, a fourth included angle α4 between a side wall of the second isolation portion 1222 and the side wall of the conductive portion 121 is an obtuse angle, and a fifth included angle α5 between the side wall of the first isolation portion 1221 and the side wall of the second isolation portion 1222 is an obtuse angle. The above-described arrangement allows the side wall of the isolation structure 12 facing the isolation opening 1201 to form an arc-like guide surface (as shown by dashed lines in the figure). In the process of preparing the inorganic encapsulation layer, the film-forming material may move smoothly along the side wall, so that the film-forming material continuously forms a film on the side wall and the light-emitting device, forming an encapsulation unit with a relatively uniform film thickness, thereby improving the stress resistance and encapsulation effect of the film layer of the encapsulation unit.

In another implementation of this embodiment, referring to FIG. 5, the isolation portion 122 further includes a third isolation portion 1223 located on a side of the first isolation portion 1221 away from the substrate 11. The third isolation portion 1223 extends relative to the first isolation portion 1221 toward the isolation opening 1201. A sixth included angle α6 between a side of the third isolation portion 1223 facing the substrate 11 and the side of the first isolation portion 1221 facing the substrate 11 is an obtuse angle.

In the above structure, the third isolation portion 1223 extends relative to the first isolation portion 1221 to form an undercut structure at which an entire surface of the evaporated film layer may be disconnected. In addition, the sixth included angle α6 between the side of the third isolation portion 1223 facing the substrate 11 and a side of the first isolation portion 1221 facing the isolation opening is an obtuse angle, which allows a surface on a side of the isolation structure 12 facing the isolation opening 1201 to form a C-shaped guide surface (shown by dashed lines in the figure), thereby increasing the flow smoothness of the surface. In the process of preparing the inorganic encapsulation layer, the film-forming material may move smoothly along the surface, so that the film-forming material continuously forms a film on the surface, forming an inorganic encapsulation layer with a relatively uniform film thickness, thereby improving the stress resistance and encapsulation effect of the film layer of the inorganic encapsulation layer.

Further, referring to FIG. 5 again, in this embodiment, an orthographic projection of the bottom surface on the side of the first isolation portion 1221 facing the substrate 11 on the substrate 11 is located within an orthographic projection of the top surface on the side of the conductive portion 121 away from the substrate 11 on the substrate 11, that is, the conductive portion 121 extends toward the isolation opening 1201 relative to the bottom surface of the first isolation portion 1221. Preferably, the orthographic projection of the isolation portion 122 on the substrate 11 is located within the orthographic projection of the conductive portion 121 on the substrate 11, so that the conductive portion 121 can easily overlap with the evaporated electrode.

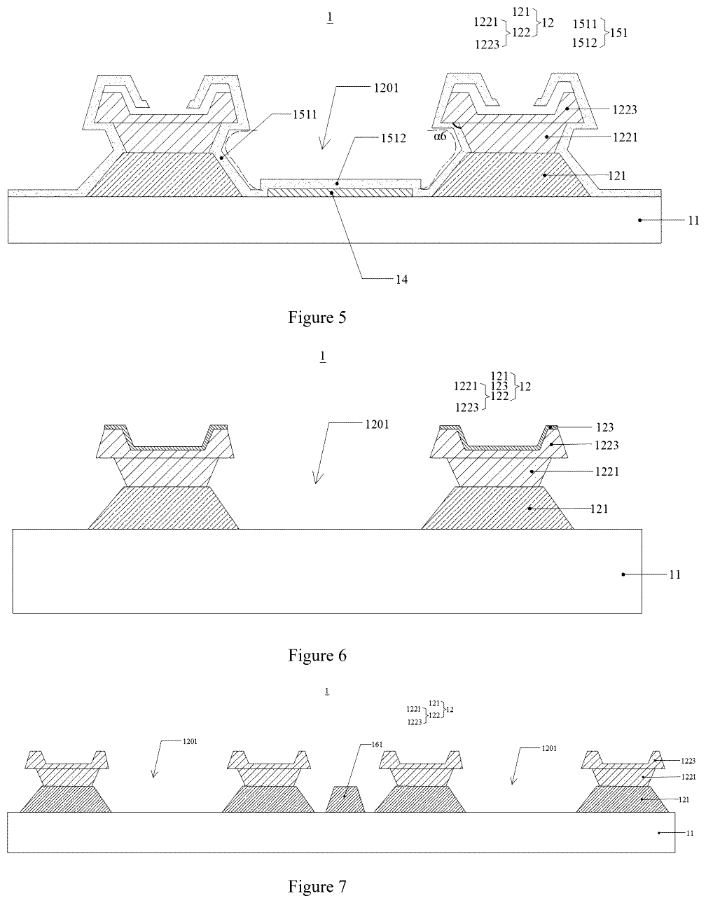

The inventors have found that when wet etching is used to pattern the organic material layer and/or the inorganic material layer to form the isolation portion 122, an etching solution easily corrodes the material layer, causing the morphology of the isolation portion 122 to fail to meet the requirements. To this end, in this embodiment, referring to FIG. 6, the isolation structure 12 further includes a blocking portion 123, which is located on a side of the isolation portion 122 away from the substrate 11. An orthographic projection of the blocking portion 123 on the substrate 11 coincides with the orthographic projection of the isolation portion 122 on the substrate 11. Optionally, the blocking portion 123 is made of a corrosion-resistant material. For example, a material of the blocking portion 123 includes titanium.

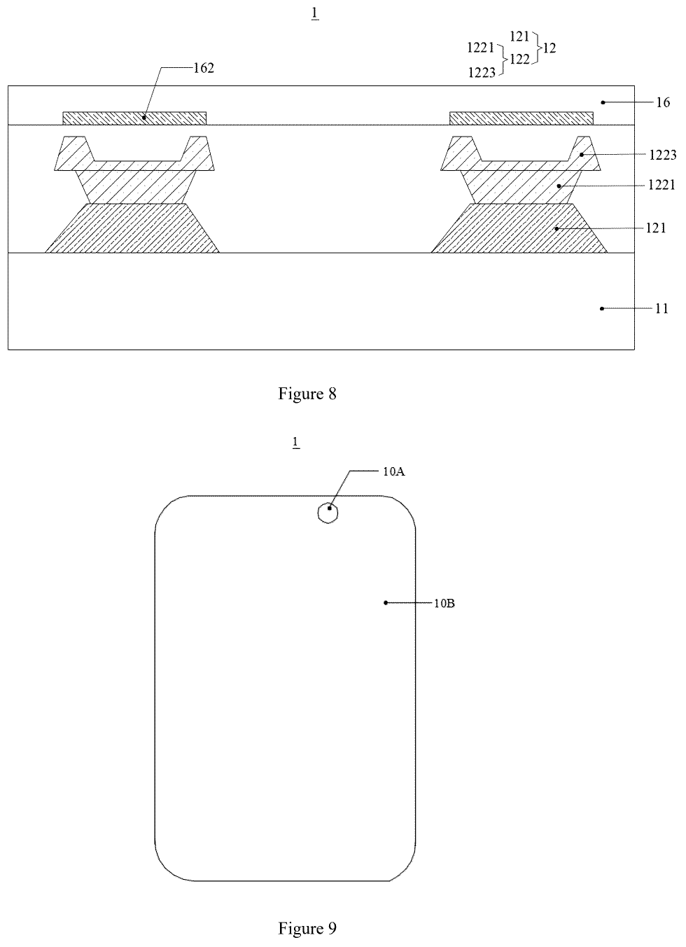

Further, a touch function can be integrated into the display panel 1. Specifically, it can be integrated into the display panel using an In-cell or on-cell method. For example, if the touch function is integrated into the display panel using the In-cell method, referring to FIG. 7, a gap is provided between adjacent isolation structures 12. The display panel 1 includes a first touch trace 161 disposed in the same layer as the conductive portion 121, the first touch trace 161 is located in the gap between the adjacent isolation structures 12, and the first touch trace 161 is insulated from the conductive portion 121. If the touch function is integrated into the display panel 1 using the on-cell method, referring to FIG. 8, the display panel 1 further includes a touch functional layer 16 located on the side of the isolation structure 12 away from the substrate 11. The touch functional layer 16 includes a plurality of second touch traces 162. In order to reduce the obstruction of light generated from the light-emitting device by each of the second touch traces 162, an orthographic projection of the second touch trace 162 on the substrate 11 at least partially overlaps with an orthographic projection of the isolation structure 12 on the substrate 11.

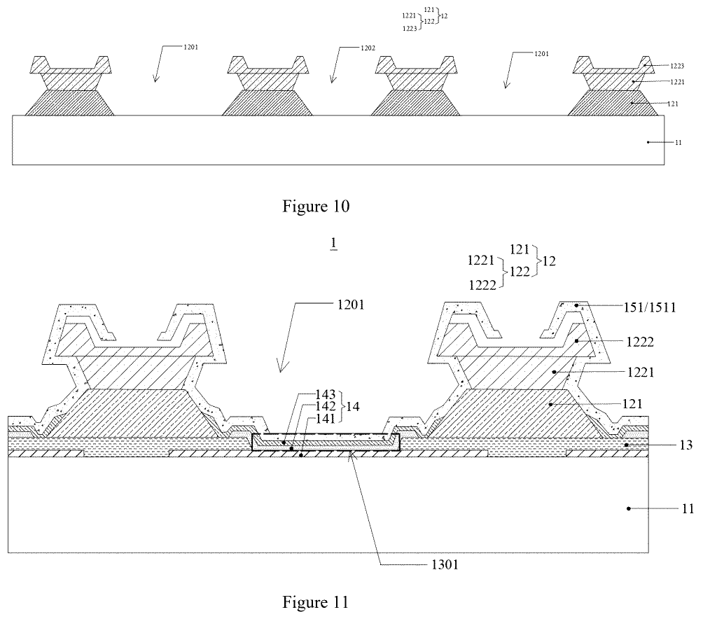

Further, in order to improve the sensitivity of an optical sensor (e.g., a camera) located below the display panel 1, in this embodiment, referring to FIGS. 9 and 10, the display panel 1 includes a first active area 10A and a second active area 10B at least partially surrounding the first active area 10A, where the optical sensor is disposed below the first active area 10A. The isolation structure 12 further includes a light-transmitting opening 1202, where the isolation structure 12 is formed with the isolation opening 1201 and the light-transmitting opening 1202 in the first active area 10A, and the isolation structure 12 is formed with only the isolation opening 1201 in the second active area 10B. In the first active area 10A, the light-transmitting opening 1202 is located adjacent to the isolation opening 1201. In order to ensure that the light-transmitting opening 1202 has good light transmittance, a light-shielding film layer is not prepared in the light-transmitting opening 1202, for example, the light-emitting material layer and an opaque conductive layer are not evaporated in the light-transmitting opening 1202. In addition, a film layer structure at the position of the light-transmitting opening 1202 in the substrate 11 can be adjusted, for example, the opaque film layer is avoided at the position of the light-transmitting opening 1202. In this way, the light transmittance of an area at the position of the light-transmitting opening 1202 can be increased to ensure that the optical sensor can capture ambient light of a sufficient intensity.

Further, in this embodiment, referring to FIG. 11, the display panel 1 further includes a pixel defining layer 13, where the pixel defining layer 13 is located on one side of the substrate 11, and the isolation structure 12 is located on a side of the pixel defining layer 13 away from the substrate 11.

The pixel defining layer 13 defines pixel openings 1301 on the substrate 11. An orthographic projection of each of the pixel openings 1301 on the substrate 11 is located within an orthographic projection of the isolation opening 1201 on the substrate 11, that is, an area of the orthographic projection of the pixel opening 1301 on the substrate 11 is smaller than an area of the orthographic projection of the isolation opening 1201 on the substrate 11.

Referring to FIG. 14 again, the light-emitting device 14 is at least partially located in the pixel opening 1301. In a direction away from the substrate 11, the light-emitting device 14 includes a first electrode 141, a light-emitting material layer 142 and a second electrode 143 that are stacked, where the second electrode 143 overlaps with the conductive portion 121. For example, the first electrode 141 can be an anode of the light-emitting device 14, and the second electrode 143 can be a cathode of the light-emitting device 14.

In this embodiment, the isolation structure 12 may define a plurality of isolation openings 1201. The arrangement of the isolation structure 12 can form film layers of light-emitting devices of different colors in different isolation openings 1201 without a fine metal mask, thereby reducing the preparation cost of the display panel. The isolation structure 12 may isolate the light-emitting material layer 142 and the second electrode 143 in the light-emitting device, so that different light-emitting devices 14 are independent of each other, thereby improving crosstalk between adjacent light-emitting devices 14 and enhancing the display effect. Furthermore, adjacent light-emitting devices 14 are independent of each other and can be independently encapsulated to improve the encapsulation yield. Furthermore, due to the presence of the isolation structure 12, each of the light-emitting material layer 142 and the second electrode 143 in the light-emitting device 14 of each color in the display panel can be prepared over its entire surface first and then patterned, thereby eliminating the need for a fine metal mask and reducing the preparation cost of the display panel.

In this embodiment, the light-emitting device 14 can be a single-layer device or a stacked device. If the light-emitting device 14 is a single-layer device, the light-emitting material layer 142 includes only one emission layer. If the light-emitting device 14 is a stacked device, the light-emitting material layer 142 includes at least two emission layers. In the following, the light-emitting device 14 is taken as a stacked device as an example. At least two emission layers 142 in the light-emitting material layer 142 have the same color. The light-emitting material layer 142 further includes a charge generation layer located between adjacent emission layers.

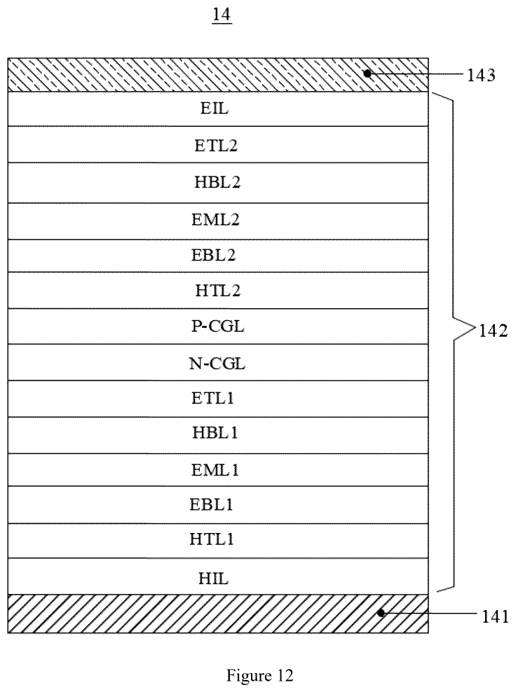

The following description takes the light-emitting device 14 as a double stacked device as an example. Referring to FIG. 12, in the direction away from the substrate 11, the light-emitting material layer 142 includes a hole injection layer (HIL), a first hole transport layer (HTL1), a first electron-blocking layer (EBL1), a first emission layer (EML1), a first hole block layer (HBL1), a first electron transport layer (ETL1), an N-type charge generation layer (N-CGL), a P-type charge generation layer (P-CGL), a second hole transport layer (HTL2), a second electron-blocking layer (EBL2), a second emission layer (EML2), a second hole block layer (HBL2), a second electron transport layer (ETL2) and an electron injection layer (EIL) that are stacked in sequence. In order to avoid a short circuit between the anode and the cathode of the light-emitting device and affecting the display effect, in this embodiment, orthographic projections of the hole injection layer, the first hole transport layer, the N-type charge generation layer and the second hole transport layer on the substrate 11 are located outside the orthographic projection of the conductive portion 121 on the substrate 11, so as to prevent the above-mentioned film layer from connecting to the second electrode 143 (cathode) through the conductive portion 121, which could result in a short circuit between the first electrode 141 and the second electrode 143.

Further, in this embodiment, two adjacent encapsulation units 151 for encapsulating light-emitting devices 14 of different colors are disconnected on the side of the isolation structure 12 away from the substrate 11, and a gap exists between the isolation structure 12 and the encapsulation unit 151 on the side of the isolation structure 12 away from the substrate 11. Two adjacent encapsulation units 151 for encapsulating light-emitting devices 14 of the same color are continuous on the side of the isolation structure 12 away from the substrate 11.

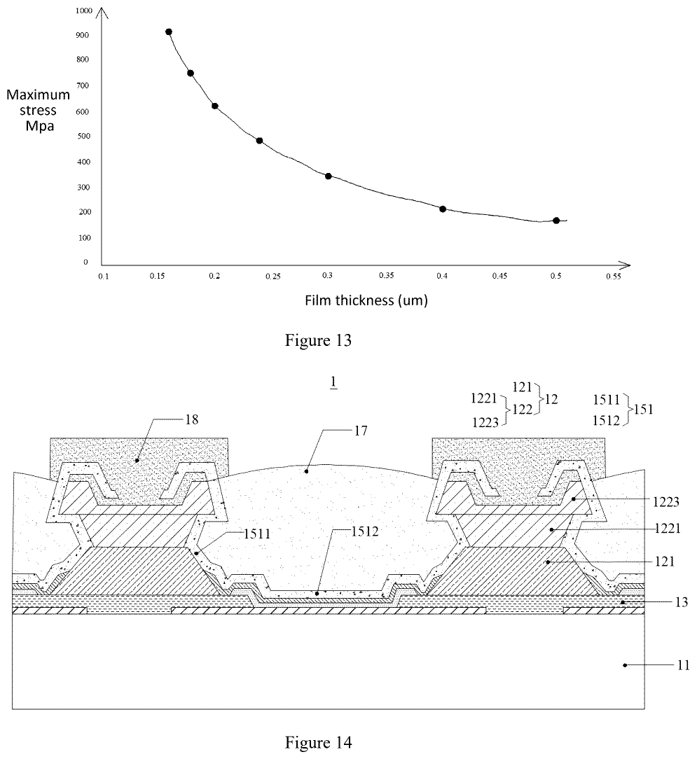

The thicker the film thickness of the encapsulation unit 151, the smaller the corresponding stress and the stronger the stress resistance. As shown in FIG. 13, the maximum stress of the film layer rapidly decays with the increase of the film thickness. For example, when the film thickness changes from 0.15 microns to 0.45 microns, the maximum stress of the film layer drops from about 1000 MPa to about 180 MPa, and the stress of the film layer is reduced to about ⅙ of the original stress.

In a possible implementation, referring to FIG. 14, the display panel 1 further includes filter units 17 and light-absorbing units 18, each of the filter units 17 is filled in the isolation opening 1201, each of the light-absorbing units 18 is disposed on a side of the isolation structure 12 away from the substrate 11, and an orthographic projection of the light-absorbing unit 18 on the substrate 11 overlaps with the orthographic projection of the isolation structure 12 on the substrate 11. In this implementation, a material of the first isolation portion 1221 includes a light-absorbing material, and the first isolation portion 1221 can be reused as the light-absorbing unit 18, where a light output color of the filter unit 17 is the same as a light-emitting color of the light-emitting device 14 in the isolation opening 12. Such a design can reduce color crosstalk between adjacent light-emitting devices 14 and improve the display effect of the display panel.

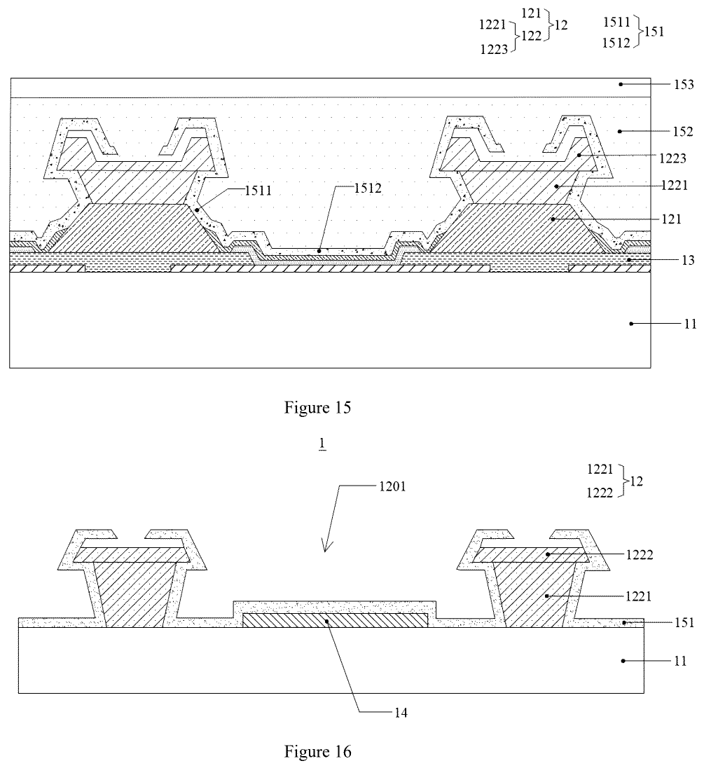

In a possible implementation, referring to FIG. 15, in this embodiment, the display panel 1 further includes a first encapsulation layer 152. The first encapsulation layer 152 is located on a side of the encapsulation unit 151 away from the substrate 11. The first encapsulation layer 152 has a flat surface on the side away from the substrate 11.

Optionally, on the side of the isolation structure 12 away from the substrate 11, the first encapsulation layer 152 fills the gap between the encapsulation unit 151 and the isolation structure 12.

Further, referring to FIG. 15 again, the display panel 1 further includes a second encapsulation layer 153 located on a side of the first encapsulation layer 152 away from the substrate 11.

Optionally, the encapsulation unit 151 and the second encapsulation layer 153 are inorganic encapsulation layers, and the first encapsulation layer 152 is an organic encapsulation layer. For example, the first encapsulation layer 151 and the second encapsulation layer 153 may be formed by means of chemical vapor deposition (CVD), and the first encapsulation layer 152 may be formed by means of ink-jet printing (IJP).

Based on the same inventive concept, referring to FIG. 16, an embodiment of the present application further provides a display panel 1, which includes a substrate 11, isolation structures 12, light-emitting devices 14 and encapsulation units 151. The isolation structures 12 are located on one side of the substrate 11 and define isolation openings 1201 in the substrate. Each of the light-emitting devices 14 is at least partially located in a corresponding one of the isolation openings 1201. Each of the encapsulation units 151 is located on a side of a corresponding one of the light-emitting devices 14 away from the substrate and extends through a corresponding one of the isolation structures 12 toward a side wall of the isolation opening 1201 to a side of the isolation structure 12 away from the substrate 11. The isolation structure 12 includes a first isolation portion 1221 and a second isolation portion 1222 that are stacked in a direction away from the substrate 11, where the second isolation portion 1222 extends toward the isolation opening 1201 relative to the first isolation portion 1221, and on a first cross-section perpendicular to a plane where the substrate 11 is located and in a direction of a line connecting centers of two adjacent isolation openings 1201, a cross-sectional shape of the first isolation portion 1221 is an inverted trapezoid. A film thickness of the encapsulation unit 151 on the first isolation portion 1221 is the same as a film thickness of the encapsulation unit on the second isolation portion 1222.

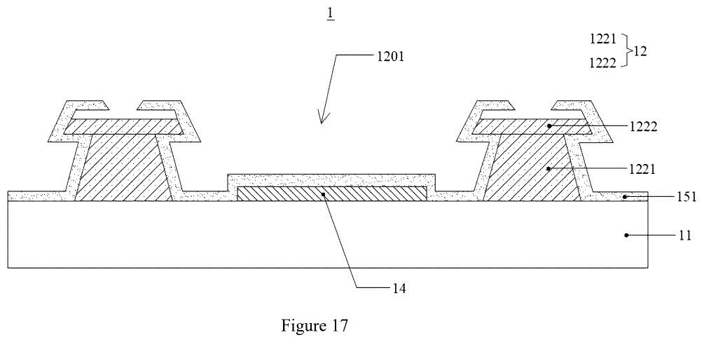

Based on the same inventive concept, referring to FIG. 17, an embodiment of the present application further provides a display panel 1, which includes a substrate 11, isolation structures 12, light-emitting devices 14 and encapsulation units 151. The isolation structures 12 are located on one side of the substrate 11 and define isolation openings 1201 in the substrate. Each of the light-emitting devices 14 is at least partially located in a corresponding one of the isolation openings 1201. Each of the encapsulation units 151 is located on a side of a corresponding one of the light-emitting devices 14 away from the substrate and extends through a corresponding one of the isolation structures 12 toward a side wall of the isolation opening 1201 to a side of the isolation structure 12 away from the substrate 11. The isolation structure 12 includes a first isolation portion 1221 and a second isolation portion 1222 that are stacked in a direction away from the substrate 11, where the second isolation portion 1222 extends toward the isolation opening 1201 relative to the first isolation portion 1221, and on a first cross-section perpendicular to a plane where the substrate 11 is located and in a direction of a line connecting centers of two adjacent isolation openings 1201, a cross-sectional shape of the first isolation portion 1221 is a trapezoid. A thickness of the encapsulation unit 151 in contact with the first isolation portion 1221 is the same as a thickness of the encapsulation unit 151 in contact with the second isolation portion 1222.

Based on the same inventive concept, an embodiment of the present application further provides an electronic device, which includes a display panel provided in the present application, or includes a display panel prepared according to a method for preparing a display panel provided in the present embodiment. The electronic device may include devices with a display function such as a mobile phone, a tablet computer, a smart wearable device, a television, a laptop computer, and a display.

An embodiment of the present application provides a display panel and an electronic device. In the display panel, isolation structures are located on a substrate and define isolation openings. Each of light-emitting devices is at least partially located in a corresponding one of the isolation openings. Each of encapsulation units is located on a side of the light-emitting device away from the substrate and extends through a corresponding one of the isolation structures toward a side wall of the isolation opening to a side of the isolation structure away from the substrate. The encapsulation unit includes a first encapsulation portion in contact with the isolation structure, and a film thickness of the first encapsulation portion is uniform. In the above structure, the film thickness of the first encapsulation portion is uniform, the overall resistance to deformation stress of the first encapsulation portion is strong, and it is not easy to rupture due to an external force. It can improve the encapsulation effect of the encapsulation unit on the light-emitting device and ensure the display effect of the display panel.

The foregoing descriptions are merely exemplary embodiments of the present application, but are not intended to limit the present application. For those skilled in the art, the present application may have various modifications and variations. Any modifications, equivalent substitutions, improvements, etc. made within the spirit and principle of the present application should fall within the scope of protection of the present application.

1. A display panel, comprising:
a substrate;
an isolation structure located on one side of the substrate, and the isolation structure encircling a plurality of isolation openings;
a light-emitting device, the light-emitting device being at least partially located within a corresponding one of the isolation openings; and
an encapsulation unit located on a side of the light-emitting device away from the substrate, and for each of the isolation openings, the encapsulation unit extending through the isolation structure toward a side wall of the isolation opening to a side of the isolation structure away from the substrate;
wherein the encapsulation unit comprises a first encapsulation portion in contact with the isolation structure, and a film thickness of the first encapsulation portion on a side wall of the isolation structure facing the corresponding isolation opening is uniform.

2. The display panel according to claim 1, wherein the encapsulation unit further comprises a second encapsulation portion covering a side of the light-emitting device away from the substrate, and a film thickness of the second encapsulation portion is uniform;

3. The display panel according to claim 2, wherein a difference in film thickness of the first encapsulation portion at different positions is less than one fifth of an average film thickness of the first encapsulation portion; and
a difference in film thickness of the second encapsulation portion at different positions is less than one fifth of an average film thickness of the second encapsulation portion.

4. The display panel according to claim 2, wherein the isolation structure comprises a conductive portion and an isolation portion; and
the isolation portion comprises a first isolation portion located on a side of the conductive portion away from the substrate, and on a first cross-section perpendicular to a plane where the substrate is located and in a direction of a line connecting centers of two adjacent isolation openings, a dimension of the first isolation portion gradually decreases from the side of the isolation portion away from the substrate toward a direction close to the substrate.

5. The display panel according to claim 4, wherein within each of the isolation openings a first included angle between a side wall of the characterized in that the first isolation portion and a bottom surface on a side of the first isolation portion facing the substrate is an obtuse angle; and
within each of the isolation openings, a second included angle between a surface on a side of the first encapsulation portion facing the isolation opening and a surface on a side of the second encapsulation portion away from the substrate is an acute angle.

6. The display panel according to claim 4, wherein a thickness of the isolation portion is 1 to 10 times a thickness of the conductive portion; and
an orthographic projection of the isolation portion on the substrate is located within an orthographic projection of the conductive portion on the substrate.

7. The display panel according to claim 4, wherein on the first cross-section, a cross-sectional shape of the conductive portion is a trapezoid;
an orthographic projection, on the substrate, of a bottom surface of the first isolation portion facing the substrate on the substrate is located within an orthographic projection, on the substrate, of a top surface of the conductive portion away from the substrate; and
within each of the isolation openings, a included third angle between a side wall of the first isolation portion facing the isolation opening and a side wall of the conductive portion facing the isolation opening is an obtuse angle.

8. The display panel according to claim 4, wherein the isolation portion further comprises a second isolation portion located on a side of the first isolation portion close to the conductive portion, and on the first cross-section, a dimension of the second isolation portion gradually increases from a side of the second isolation portion away from the substrate toward the direction close to the substrate;
the first isolation portion and the second isolation portion are made of the same material;
an orthographic projection of the second isolation portion on the substrate is located within an orthographic projection of the first isolation portion on the substrate;
within each of the isolation openings, an orthographic projection of the conductive portion on the substrate extends toward the isolation opening relative to the orthographic projection of the first isolation portion on the substrate; and
within each of the isolation openings, a fourth included angle between a side all of the second isolation portion facing the isolation opening and a side wall of the conductive portion facing the isolation opening is an obtuse angle, and a fifth included angle between a side wall of the first isolation portion facing the isolation opening and the side wall of the second isolation portion facing the isolation opening is an obtuse angle.

9. The display panel according to claim 4, wherein the isolation portion further comprises a third isolation portion located on a side of the first isolation portion away from the substrate, the third isolation portion extending relative to the first isolation portion toward the isolation opening; and
within each of the isolation openings, a sixth included angle between a side of the third isolation portion facing the substrate and a side of the first isolation portion facing the isolation opening is an obtuse angle.

10. The display panel according to claim 4, wherein the isolation structure further comprises a blocking portion on the side of the isolation portion away from the substrate
and an orthographic projection of the blocking portion on the substrate at least partially coincides with the orthographic projection of the isolation portion on the array substrate.

11-12. (canceled)

13. The display panel according to claim 4, wherein the display panel further comprises a pixel defining layer located on one side of the substrate, and the isolation structure being located on a side of the pixel defining layer away from the substrate;
the pixel defining layer defines a plurality of pixel openings on the substrate, and an orthographic projection of each of the pixel openings on the substrate is located within an orthographic projection of each of the isolation opening on the substrate;
in a direction away from the substrate, the light-emitting device comprises a first electrode, a light-emitting material layer, and a second electrode that are stacked, the second electrode overlapping with the conductive portion; and
an orthographic projection of the first electrode on the substrate partially overlaps with an orthographic projection of the isolation structure on the substrate.

14. (canceled)

15. The display panel according to claim 1, wherein two adjacent encapsulation units for encapsulating two light-emitting devices of different colors are separated on the side of the isolation structure away from the substrate; and
at least two adjacent encapsulation units for encapsulating at least two light-emitting devices of the same color are continuous on a side of the isolation structure away from the substrate.

16. (canceled)

17. The display panel according to claim 24, wherein the display panel further comprises a second encapsulation layer located on the side of the encapsulation unit away from the substrate; and
the second encapsulation layer further fills the gap.

18. A display panel, comprising:
a substrate;
an isolation structure located on one side of the substrate, and the isolation structure encircling a plurality of isolation openings;
a light-emitting device, the light-emitting device being at least partially located within a corresponding one of the isolation openings; and
an encapsulation unit located on a side of the light-emitting device away from the substrate, and for each of the isolation openings, the encapsulation unit extending through the isolation structure toward a side wall of the isolation opening to a side of the isolation structure away from the substrate;
wherein the isolation structure comprises a first isolation portion and a second isolation portion that are stacked in a direction away from the substrate, the second isolation portion extending toward the isolation opening relative to the first isolation portion, and on a first cross-section perpendicular to a plane where the substrate is located and in a direction of a line connecting centers of two adjacent isolation openings, a cross-sectional shape of the first isolation portion being an inverted trapezoid; and
a thickness of the encapsulation unit in contact with the first isolation portion is the same as a thickness of the encapsulation unit in contact with the second isolation portion.

19. A display panel, comprising:
a substrate;
an isolation structure, located on one side of the substrate, and the isolation structure encircling a plurality of isolation openings;
a light-emitting device each of the light-emitting device being at least partially located within a corresponding one of the isolation openings; and
an encapsulation unit, located on a side of the light-emitting device away from the substrate, and for each of the isolation openings encapsulation unit extending through a corresponding one of the isolation structure toward a side wall of the isolation opening to a side of the isolation structure away from the substrate;
wherein the encapsulation unit comprises a first encapsulation portion in contact with the isolation structure, and a film thickness of the first encapsulation portion on a side wall of the isolation structure facing the isolation opening is uniform.

20. (canceled)

21. The display panel according to claim 2, wherein an average film thickness of the second encapsulation portion is greater than an average film thickness of the first encapsulation portion.

22. The display panel according to claim 1, wherein an average film thickness of the first encapsulation portion is the same as an average film thickness of the second encapsulation portion.

23. The display panel according to claim 2, wherein a difference between an average film thickness of the first encapsulation portion and an average film thickness of the second encapsulation portion is less than one tenth of the average film thickness of the first encapsulation portion or one tenth of the average film thickness of the second encapsulation portion.

24. The display panel according to claim 1, wherein two adjacent encapsulation units for encapsulating two light-emitting devices are separated on the side of the isolation structure away from the substrate; and
a gap is provided between the isolation structure and the encapsulation unit on the side of the isolation structure away from the substrate.
